(19) United States
(12) Patent Application Publication
(10) Pub. No.: US 2013/0249577 A1
(43) Pub. Date: Sep. 26, 2013

(54) ACCELERATED LIFETIME TESTING APPARATUS AND METHODS FOR PHOTOVOLTAIC MODULES

(71) Applicants: Jeffrey Todd Knapp, Golden, CO (US); Samuel Demtsu, Thornton, CO (US); Scott L. French, Superior, CO (US)

(72) Inventors: Jeffrey Todd Knapp, Golden, CO (US); Samuel Demtsu, Thornton, CO (US); Scott L. French, Superior, CO (US)

(73) Assignee: PrimeStar Solar, Inc., Arvada, CO (US)

(21) Appl. No.: 13/426,011

(22) Filed: Mar. 21, 2012

(51) Int. Cl. G01R 31/00

(52) U.S. Cl. 324/750.03; 324/750.01

(57) ABSTRACT

Methods and apparatus for performing an accelerated lifetime test on a photovoltaic device are provided. The method can include positioning a first photovoltaic device in a first holder adjacent to a light guide such that a transparent surface of the photovoltaic device faces the light guide, directing light emitted from a first light source into the light guide, and redirecting the light emitted from the first light source within the light guide to illuminate the transparent surface of the photovoltaic device.

### FIELD OF THE INVENTION

The subject matter disclosed herein relates generally to the testing photovoltaic modules. More particularly, the subject matter is related to methods and apparatus for testing the endurance of photovoltaic (PV) modules over a simulated lifetime.

### BACKGROUND OF THE INVENTION

Currently available accelerated lifetime testers (ALTs) chambers for testing the long-term stability of photovoltaic (PV) devices employ lighting elements positioned at proximate a sunny-side face of a given PV device. In order to test multiple PV panels simultaneously, a light bank of multiple light elements can be employed to illuminate multiple PV devices simultaneously. Additionally, in order to simulate the full light spectrum of the sun (e.g., radiation with a wavelength between about 350 nm and about 800 nm, such as about 360 nm to about 760 nm) and/or the intensity of the sunlight received by the PV device in the field, several light elements can be used. The lighting elements can typically include xenon arc lamps, metal halide lamps, etc., and may have a reflective housing to ensure the light is directed to the PV device(s).

However, the lighting elements can become hot during use, and may lead to unnatural heating of the PV devices to temperatures above which would be present in the field, especially when positioned close to the PV device(s) and/or when the light is focused directly onto the surface of the PV device. Thus, the lighting elements are typically spaced sufficiently far from the PV device(s) to reduce the heating effect from the lighting elements. As such, testing multiple PV devices using the light bank of such lighting elements requires a substantial amount of space.

Therefore, a need exists for a method and apparatus for performing an accelerated lifetime test of a PV device in a smaller space, in order to reduce the physical footprint required for an ALT chamber.

### BRIEF DESCRIPTION OF THE INVENTION

Aspects and advantages of the invention will be set forth in part in the following description, or may be obvious from the description, or may be learned through practice of the invention.

Methods are generally provided for performing an accelerated lifetime test on a photovoltaic device. In one embodiment, the method can include positioning a first photovoltaic device in a first holder adjacent to a light guide such that a transparent surface of the photovoltaic device faces the light guide, directing light emitted from a first light source into the light guide, and redirecting the light emitted from the first light source within the light guide to illuminate the transparent surface of the photovoltaic device.

Apparatus is also generally provided for performing an accelerated lifetime test on a photovoltaic device. For example, the apparatus can include a first light source, a light guide positioned to receive light from the light source, and a mounting system configured to hold a photovoltaic device such that a transparent surface of the photovoltaic device faces the light guide. The light guide is generally configured to redirect light emitted from the light source onto the transparent surface of the photovoltaic device.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 shows a perspective view of an exemplary testing chamber according to one embodiment;

FIG. 2 shows a cross-sectional view of the exemplary testing chamber of FIG. 1,

FIG. 3 shows a perspective view of an exemplary testing chamber according to another embodiment;

FIG. 4 shows a cross-sectional view of the exemplary testing chamber of FIG. 3

FIG. 5 shows an exemplary light guide for use in the exemplary testing chamber of FIG. 1;

FIG. 6 shows an exemplary light guide for use in the exemplary testing chamber of FIG. 1;

FIG. 7 shows an exemplary light guide for use in the exemplary testing chamber of FIG. 1;

FIG. 8 shows an exemplary light guide for use in the exemplary testing chamber of FIG. 1.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

Apparatus and methods are provided for performing an accelerated lifetime test on a PV device (i.e., solar panel). The apparatus and methods can simulate cycles of illumination and dark periods that the PV device is exposed to in the field (e.g., to simulate day and night cycles). Embodiments of the presently disclosed apparatus and methods can allow for multiple PV devices to be tested in a relatively small space. Additionally, embodiments of the presently disclosed apparatus and methods can inhibit and/or prevent heating of the PV devices from the light source(s) used to illuminate the PV devices.

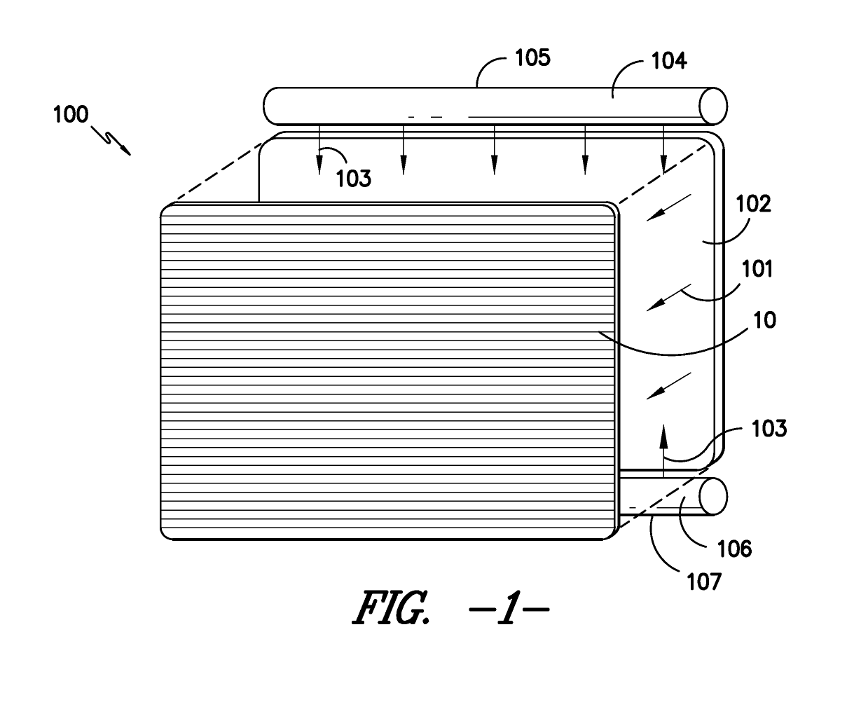

One embodiment of an apparatus 100 for performing an accelerated lifetime test on a PV device or module 10 is shown in FIG. 1. The accelerated lifetime testing apparatus generally includes a light guide 102 positioned to receive light beams 103 from a first light source 104 and optional second light source 106. Generally, the light guide 104 is configured to redirect light emitted from the light sources 104, 106 onto the transparent surface 11 of the photovoltaic device 10, with the transparent surface 11 permitting the light to reach the active regions of the photovoltaic device 10. Additional light sources may also be positioned so that light emitted from such additional light sources can be directed into the light guide.

As stated, the light guide 104 can generally be configured to redirect light emitted from the first light source 104, optional second light source 106, and any other light sources present in the apparatus 100 onto the transparent surface 11 of the photovoltaic device 10. The light guide 102 can, in one embodiment, redirect the emitted light from the first light source 104 and optional second light source 106 in a substantially uniform manner onto the transparent surface 11 of the PV device 10. Thus, the entire surface area of the transparent surface 11 of the PV device 10 can be exposed to substantially the same light, especially in terms of intensity, wavelength spectrum, etc. As such, the PV device 10 can be tested uniformly in the apparatus 100.

As shown, the light guide 102 can redirect light from the light sources 104, 106 positioned on a side edge of the light guide 102 in a manner to illuminate the transparent surface(s) 11 of the PV device(s) 10. Such distribution and redirection of the light in the light guide can be accomplished in a variety of manners, such as through the use of bumps, ridges, and/or diffractive optical elements. For example, diffractive and/or diffusive optical elements can be included within the light guide 102, and the diffractive and/or diffusive optical elements can have increasing size and/or density within the construction of the light guide 102 as a function of distance away from the light source 104, 106. The use of various configurations of such diffractive and/or diffusive optical elements as part of a light guide 102 is commonly associated with the improved lighting of LCD (liquid crystal display) panels, in terms of, e.g., achieved brightness and uniformity, and such configurations are considered to be within the scope of the present system.

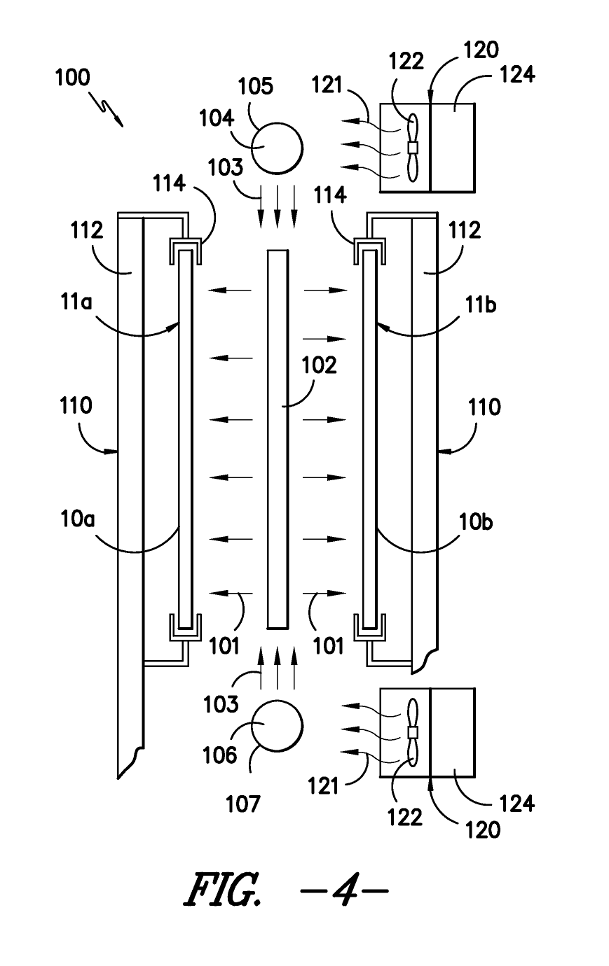

FIGS. 5-8 show exemplary light guides 102 that can be used in the embodiments of FIG. 1. Although each of these exemplary light guides 102 are discussed in greater detail below, it should be understood that any suitable light guide 102 can be utilized in accordance with the present disclosure.

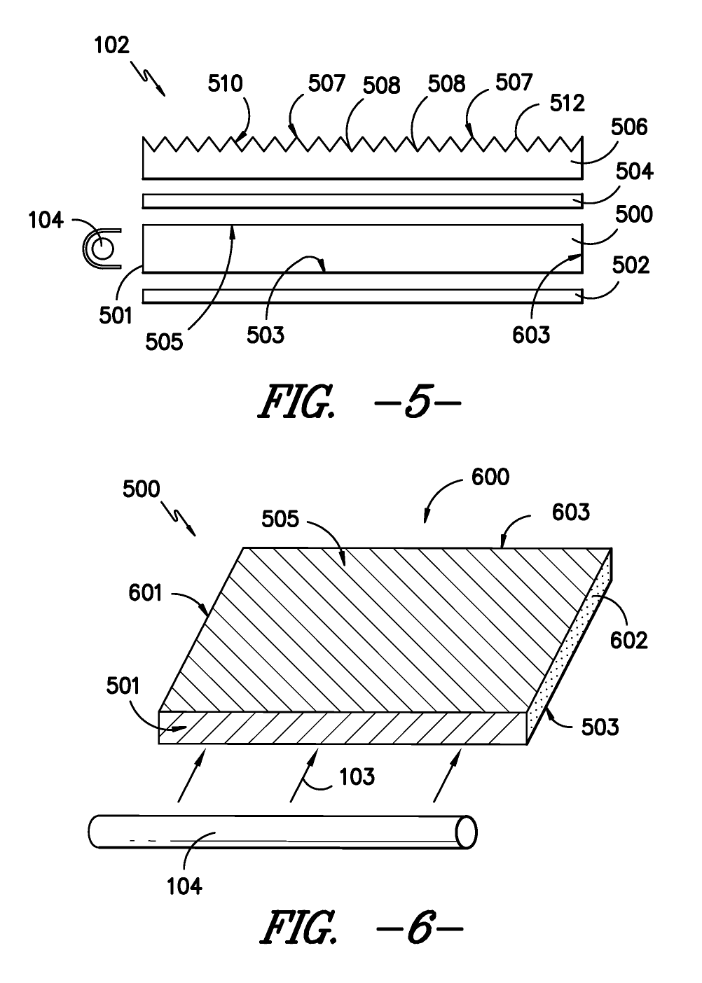

Referring to FIG. 5, an exemplary light guide 102 is shown adjacent to a light source 104. In this embodiment, the light guide 102 generally includes a light guide plate 500, a reflective plate 502, a diffusion plate 504, and a prism plate 506. As show, the light source 104 generally directs light into the light guide plate 502 at its side surface 501. The light beams may propagate between a bottom surface 503 and a light emitting surface 505 toward an opposite end surface 507 of the light guide plate 500 by total internal reflection (e.g., as discussed below with respect to FIG. 6), or may be output through the light emitting surface directly. Further, the bottom surface 503 may include structures such as dots formed thereon or facets cut therein and arranged in a pattern (not shown). Light beams encountering any of these structures are diffusely or specularly reflected, so that they are emitted through the light emitting surface 505.

Referring to FIG. 6, an exemplary light guide plate 500 (e.g., for use with the embodiment of FIG. 5) is generally shown. The light guide plate 500 comprises a substrate 600 having a light incident surface 501, a light emitting surface 505 adjacent to the light incident surface 501, a bottom surface 503 opposite to the light emitting surface 505, and side surfaces 601, 602 and 603. In one particular embodiment, the light incident surface 501 and the light emitting surface 505 can be provided with anti-reflection films (not labeled), and the bottom surface 503 and the side surfaces 601, 602, and 603 can be provided with reflective films (not labeled). As such, when light beams 103 from the light source 104 are directed on the light incident surface 501 of the light guide plate 500, most of the light beams pass through the light incident surface 501, and relatively few light beams 103 are reflected by the light incident surface 501. This reduces loss of light and enhances the light utilization efficiency of the light guide plate 500. Likewise, when the internal light beams 103 within the light guide plate 500 reach the light emitting surface 505, the light can readily pass through the light emitting surface 505. Alternatively, the reflective surfaces of the bottom surface 503 and the side surfaces 601, 602, and 603 can redirect light within the light guide plate 500 such that nearly all of the light beams 103 received through the light incident surface 501 is eventually directed out of the light emitting surface 505.

Referring again to FIG. 5, the light exiting the light emitting surface 505 of the light guide plate 500 then passes through the diffusion plate 504 and the prism plate 506. The diffusion plate 104 can be, for example, a film or sheet configured to uniformly diffuse the emitted light exiting the light emitting surface 505. The prism plate 506 can be, for example, ridged with peaks 507 and valleys 508 across the surface 510 oppositely positioned from light guide plate 500. Thus, the prism plate 506 can collimate the light beams exiting the light guide 102 in order to improve uniformity and brightness across the light guide 102.

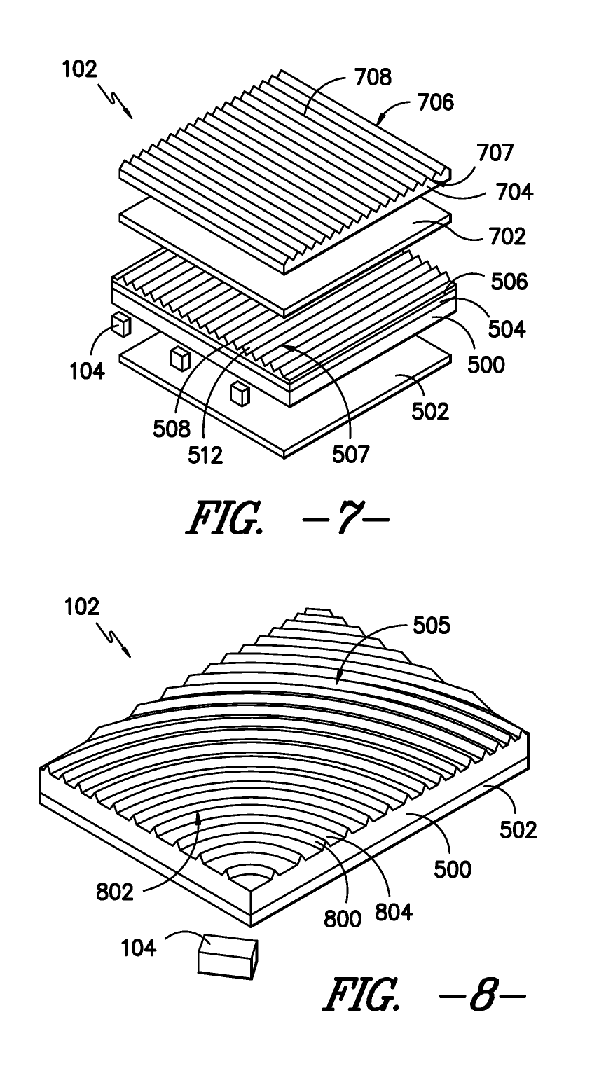

In the embodiment of FIG. 5, a single prism plate 506 is shown having the peaks 507 and valleys 508 define ridges 512 extending substantially parallel to each other in a first direction in the surface 510. However, additional prism plates may be present in the light guide 102. For example, in the embodiment shown in FIG. 7, a second diffusion sheet 702 and a second prism plate 704 is shown in the exemplary light guide 102. In this embodiment, the second prism plate 704 has peaks 706 and valleys 707 that define ridges 708 that are oriented in a second direction that is different than the first direction (e.g., substantially perpendicular).

Although shown as separate components, it is noted that the prism plate 506 and 704 (along with the optional diffusion sheets 504, 702) may form an integral part of the light guide plate 500 (i.e., may form the light emitting surface 505).

FIG. 8 shows yet another exemplary embodiment of a light guide 102. In this embodiment, the light source 104 can be positioned near a corner of the light guide plate 500. In this embodiment, the light emitting surface 505 of the light guide plate 500 is patterned with a plurality of arc-shaped ridges 800 defined by peaks 802 and valleys 804 (i.e., arcuate protrusions of triangular cross-section). Again, although shown as a single component, it is noted that the light emitting surface 505 can be formed with a separate prism plate (along with an optional diffusion sheet), as shown above with respect to FIGS. 5 and 7.

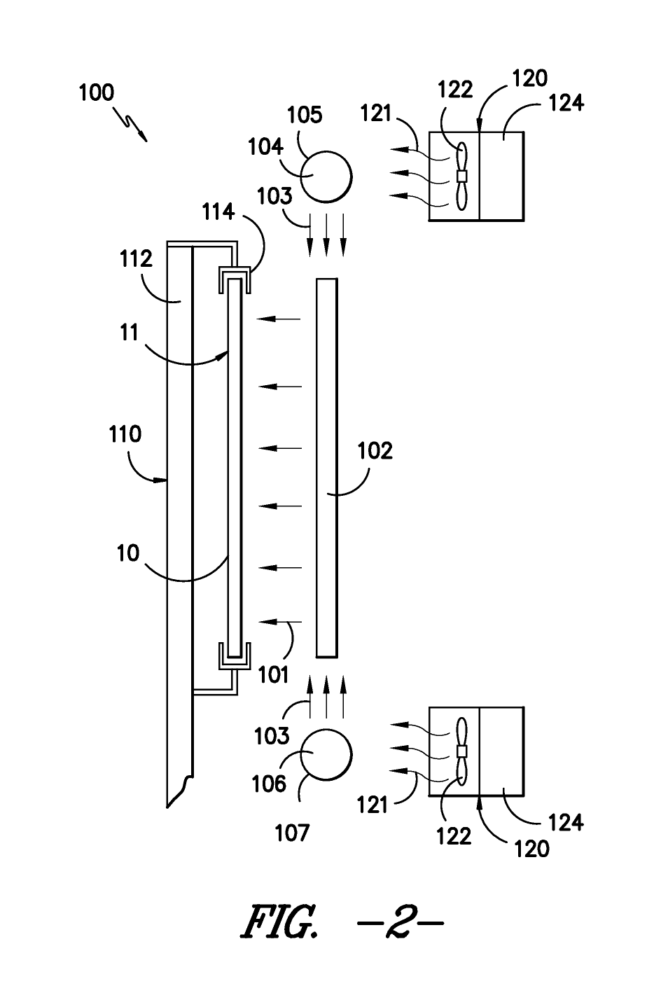

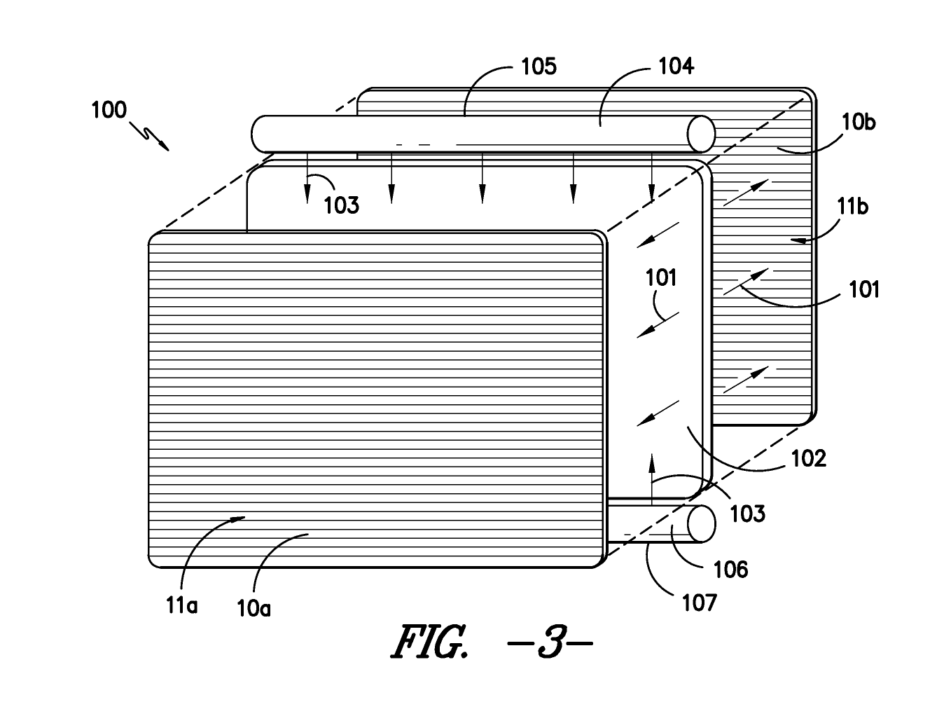

As stated, FIGS. 1-2 show an embodiment where the light guide 104 is configured to redirect light emitted from the light sources 104, 106 onto a single PV device 10. However, in other embodiments, the light guide 102 can be configured to redirect light emitted from the light sources 104, 106 onto multiple PV devices 10. For example, as shown, the light guide 102 is configured to redirect light from the light sources 104, 106 onto the transparent surfaces 11a, 11b, respectively, of a first PV device 10a and a second PV device 10b.

For example, the embodiments of FIGS. 5-8 can be utilized without a reflective plate or surface and instead with an opposite, second light emitting surface (including, for example, additional diffusion sheets and/or prism plates).

As more particularly shown in FIGS. 2 and 4, the PV device(s) 10 are shown loaded in a mounting system 110 that is generally configured to hold each PV device 10, while exposing the transparent surface 11 to light redirected from the light guide 102. Thus, the mounting system 110 generally can position each PV device 10 such that its transparent surface 11 faces the light guide 102, while the transparent surface remains exposed. For example, the embodiment shown includes a frame assembly 112 and brackets 114 configured to hold the PV device 10. However, any suitable mounting system 110 can be utilized to removably hold the PV modules 10, as long as the transparent surface 11 is substantially unblocked to receive light from the light guide 102 during testing.

In one embodiment, the photovoltaic device(s) 10 can be exposed to a series of alternating illumination periods and dark periods in order to simulate day and night cycles found with exposed in the field. As such, the PV device(s) 10 can be exposed to light in a manner that simulates the natural sunlight, as would be found in the field. Additionally, the PV device(s) 10 can be electrically connected to function as if set in actual operation.

The light sources 104, 106 can be any suitable light source. In one particular embodiment, the light source 104, 106 can simulate the light spectrum of the sun (e.g., radiation with a wavelength between about 350 nm and about 800 nm, such as about 360 nm to about 760 nm). For example, suitable light sources 104, 106 can include xenon arc lamps, metal halide lamps, fiber optic lighting, LED lamps, fluorescent lamps (e.g., CCFLs), etc., or combinations thereof

The light sources 104, 106 can be, in particular embodiments, included within a light housing 105, 107, respectively, that can be configured to direct the light emitted from the light sources 104, 106 into the light guide 102. For example, the light housing 105, 107 can be reflector housing having a reflective back surface and a front window, thus helping to maximize the use of the light generated by a given light source 104, 106.

In the embodiments shown in FIGS. 2 and 4, a cooling system 120 is positioned and configured to cool its respective light source 104, 106. The cooling system can, for example, include a fan 122 configured to flow a cooling gas 121 past the light source 104, 106 (e.g., between the light source 104 or 106 and the light guide 102 as shown, and/or between the photovoltaic device 10 and the light guide 102). The cooling gas 121 can be, in one embodiment, atmospheric air. In one embodiment, the cooling gas can be room temperature. Alternatively, the cooling gas can be passed through a cooling device 124, in order to reduce the temperature of the cooling gas below room temperature prior to flowing past the light source 104, 106.

The apparatus 100 can be utilized in a method of performing an accelerated lifetime test on a photovoltaic device. These methods can replicate a typical lifetime of exposure to the sun in a relatively short and controlled simulation. The testing cycle begins by illuminating the transparent surface 11 of the photovoltaic module 10 using the light guide 102. Upon turning the light sources 102, 104 on, the temperature of the testing chamber may rise due to radiation energy emitted from the light sources 102, 104. As stated, the rate of the temperature rise can be somewhat controlled via a cooling system 120 used in conjunction with the light sources 104, 106. In one embodiment, the temperature of the PV device 10 can be allowed to rise a targeted amount (e.g., can increase 25° C. or less) during an “on” cycle. Once the target temperature is reached, the light sources 104, 106 can be turned off (i.e., going dark), and the PV device's temperature can be reduced back to the initial temperature to complete a testing cycle.

The length of the lighted portion (i.e., light sources turned on) and the dark portion (i.e., light sources turned off) of the testing cycles can be adjusted as desired. In one embodiment, the lighted portion (i.e., light sources turned on) of the testing cycle can last long enough to raise the temperature of the PV device about 5° C. to about 15° C. (e.g., about 15 minutes to about 2 hours).

This testing cycle can be repeated any number of times to replicate being deployed in the field over an extended period. Once the desired number of testing cycles has been completed, the tester can remove the PV modules 10 for further study.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A method of performing an accelerated lifetime test on a photovoltaic device, the method comprising:
positioning a first photovoltaic device in a first holder adjacent to a light guide such that a transparent surface of the photovoltaic device faces the light guide;
directing light emitted from a first light source into the light guide; and, redirecting the light emitted from the first light source within the light guide to illuminate the transparent surface of the photovoltaic device.

2. The method as in claim 1, further comprising:
positioning a second photovoltaic device in a second holder such that a transparent surface of the second photovoltaic device faces the light guide; and,
redirecting the light emitted from the light source within the light guide such that redirected light illuminates the transparent surface of the second photovoltaic device.

3. The method as in claim 2, wherein the light guide is positioned between the first photovoltaic device and the second photovoltaic device.

4. The method as in claim 1, further comprising:
exposing the first photovoltaic device to a series of alternating illumination periods and dark periods.

5. The method as in claim 1, further comprising:
cooling the light source.

6. The method as in claim 1, further comprising:
flowing a cooling gas between the light source and the light guide.

7. The method as in claim 6, wherein the cooling gas comprises atmospheric air.

8. The method as in claim 6, further comprising:
passing the cooling gas through a coolant device.

9. The method as in claim 1, further comprising:
flowing a cooling gas between the first photovoltaic device and the light guide.

10. The method as in claim 1, further comprising:
directing light emitted from a second light source into the light guide; and,
redirecting the light emitted from the second light source within the light guide to illuminate the transparent surface of the photovoltaic device.

11. The method as in claim 10, wherein the light guide is positioned between the first light source and the second light source.

12. An apparatus for performing an accelerated lifetime test on a photovoltaic device, comprising:
a first light source;
a light guide positioned to receive light from the light source; and,
a mounting system configured to hold a photovoltaic device such that a transparent surface of the photovoltaic device faces the light guide,
wherein the light guide is configured to redirect light emitted from the light source onto the transparent surface of the photovoltaic device.

13. The accelerated lifetime testing apparatus as in claim 12, further comprising:
a second mounting system configured to hold a second photovoltaic device such that a second transparent surface of the second photovoltaic device faces the light guide.

14. The accelerated lifetime testing apparatus as in claim 13, wherein the light guide is configured to redirect light emitted from the light source onto the second transparent surface of the second photovoltaic device.

15. The accelerated lifetime testing apparatus as in claim 12, further comprising:
a second light source positioned to illuminate light into the light guide.

16. The accelerated lifetime testing apparatus as in claim 12, further comprising:
a cooling fan adjacent to the first light source and configured to flow a cooling gas between the light source and the light guide.

17. The accelerated lifetime testing apparatus as in claim 16, further comprising:
a coolant device positioned and configured such that the cooling gas is cooled prior to flowing between the light source and the light guide.

18. The accelerated lifetime testing apparatus as in claim 16, further comprising:
a second light source positioned to illuminate light into the light guide; and,
a second cooling fan adjacent to the second light source and configured to flow a cooling gas between the second light source and the light guide.
